(19) United States
(12) Patent Application Publication
(10) Pub. No.: US 2012/0060918 A1
(43) Pub. Date: Mar. 15, 2012

(54) ENERGY CONVERSION DEVICE FOR PHOTOVOLTAIC CELLS

(76) Inventor: Mark B. Spitzer, Sharon, MA (US)

(21) Appl. No.: 13/210,791

(22) Filed: Aug. 16, 2011

Related U.S. Application Data
(60) Provisional application No. 61/374,050, filed on Aug. 16, 2010.

(51) Int. Cl. H01L 31/0232

(52) U.S. Cl. 136/257

(57) ABSTRACT

An energy conversion device is provided for use, for example, in a photovoltaic solar cell. The device includes an up conversion composite material disposed in cavities in a semiconductor material or in a heat spreader bonded to the solar cell. The up conversion composite material is formed from a mixture of at least two different up conversion materials formed as crystal grains dispersed within an optically transmitting dispersion medium. The up conversion materials may include a crystal material doped with dopant atoms capable of absorbing photons having wavelengths longer than an absorption edge of the semiconductor material and emitting photons having wavelengths shorter than the absorption edge. In this manner, more photons can be utilized in the solar cell and optical coupling between the semiconductor material and the up conversion material is increased,

### CROSS REFERENCE TO RELATED APPLICATIONS

This application claims the benefit under 35 U.S.C. §119(e) of U.S. Provisional Patent Application No. 61/374,050, filed on Aug. 16, 2010, the disclosure of which is incorporated by reference herein.

### STATEMENT REGARDING FEDERALLY SPONSORED RESEARCH OR DEVELOPMENT

N/A

### BACKGROUND OF THE INVENTION

Conventional photovoltaic cells made from a single absorbing semiconductor such as silicon (Si) are limited in efficiency to less than 30%. The fundamental energy loss mechanisms in single-absorber cells that are used in both concentrator and flat plate modules arise from the mismatch between the solar spectrum and the absorption spectrum of the semiconductor, largely determined by the optical band gap, E_{G}, of the semiconductor. Photons with energy greater than E_{G} can be absorbed, and a properly designed solar cell can extract some of the energy delivered by absorbed photons as electricity. The photon wavelength corresponding to E_{G} is termed the absorption edge. Photons with wavelength shorter than the absorption edge can be absorbed by a solar cell to generate electricity. Photons with wavelength longer than the absorption edge cannot be absorbed by a conventional solar cell made from a single absorbing semiconductor. Solar cells made from absorbing materials of lower E_{G} produce more photo-generated current than materials of higher E_{G}, because more of the solar spectrum can be absorbed when the absorption edge occurs at a comparatively long wavelength. Generation of a high solar cell current requires a low value of E_{G}. For example, current generated by a Si solar cell (E_{G}=1.115 eV) is generally higher than current generated by a gallium arsenide (GaAs) solar cell (E_{G}=1.43 eV).

The solar cell operating voltage is generally higher in cells made from materials with higher E_{G}. For example, a GaAs solar cell yields a higher operating voltage than a Si solar cell. The attainment of a high solar cell voltage requires a large value of E_{G}. The power delivered to an external circuit by the solar cell is the product of (i) the voltage at the terminals of the cell, and (ii) the photo-generated current supplied by the cell at the terminals. Thus there is an optimum range of values of E_{G} that delivers the most power. Absorbing materials with E_{G} ranging between 1.0 and 1.5 eV appear to be best suited for single absorber solar cells. In any single absorber solar cell with E_{G} in this optimal range, some incident solar energy will be lost owing to photons with energy less than E_{G}.

Tandem solar cells known in the prior art are made from two or more absorbing semiconductor solar cells and address energy loss by stacking solar cells with different E_{G} in series optically, so that photons not absorbed in the first solar cell can be transmitted to the second cell in the optical series stack. By using two or more different absorbing semiconductors, tandem solar cells can absorb the high energy part of the solar spectrum in a cell operating at a higher voltage. The light that is not absorbed by the first solar cell is passed to the second where it can be absorbed by a material operating at a lower voltage. In this way a tandem cell attains higher peak efficiency than a single junction cell, although it is more complex and expensive to manufacture.

### SUMMARY OF THE INVENTION

The present invention relates to an energy conversion device that can be used, for example, in a photovoltaic solar cell. The device minimizes losses due to non-absorption and thermalization in solar cells by up converting the energies of incident photons prior to absorption by the semiconductor and improves the optical coupling between the semiconductor and an up conversion material.

In one embodiment, the device includes a layer of a photon-absorbing semiconductor material having a front photon-receiving surface and a back surface. The semiconductor material has an absorption edge, such that photons having wavelengths at or shorter than the absorption edge are absorbed in the semiconductor material to generate electron-hole pairs. An up conversion composite material is disposed within cavities formed in the photon-absorbing semiconductor material extending inwardly from the back surface. In another embodiment, the up conversion composite material is disposed within cavities formed in a heat spreader bonded to the solar cell.

In one embodiment, the up conversion composite material comprises a mixture of at least two different up conversion materials formed as crystal grains dispersed within a dispersion medium comprising an optically transmitting material. Each up conversion material includes a crystal material doped with dopant atoms capable of absorbing photons having wavelengths longer than the absorption edge of the semiconductor material and emitting photons having wavelengths shorter than the absorption edge. The up conversion composite material may include at least two different crystal materials doped with dopant atoms, the dopant atoms of each crystal material being different to absorb photons having different wavelengths.

The device provides better optical coupling between the solar cell and the up converter material than in prior art devices that incorporate an up conversion process. The use of multiple up conversion materials overcomes the use of a single up-converter material that only absorbs over a few narrow bands of the spectrum. In a concentrator solar cell, the device improves electrical and thermal coupling between the solar cell and the heat sink, in contrast to prior art devices in which a single up conversion material applied to the back of a concentrator solar cell interferes with the electrical and thermal contact to the concentrator heat sink.

### DESCRIPTION OF THE DRAWINGS

The foregoing features of this invention, as well as the invention itself, may be more fully understood from the following description of the drawings in which:

FIG. 1 is a schematic representation of a silicon solar cell;

FIG. 2 is an energy band diagram of a silicon solar cell showing allowed bands and energy band gap, where the abscissa is a distance from the front surface upon which light is incident and the ordinate is energy and also showing non-absorption loss;

FIG. 3 is an energy band diagram illustrating thermalization energy loss;

FIG. 4 is a schematic representation of a conversion device in accordance with exemplary embodiments of the invention;

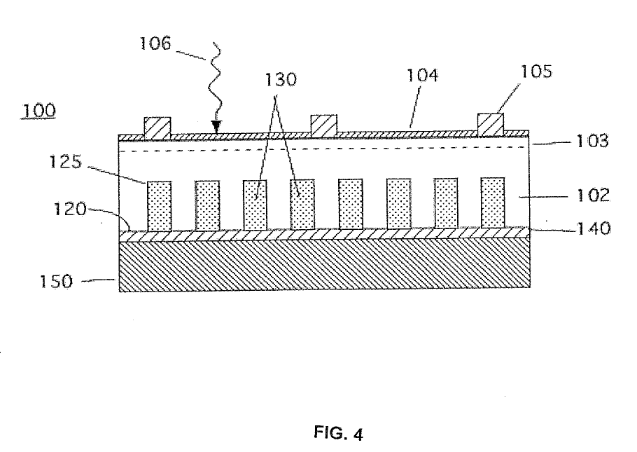

FIG. 5 is a schematic representation of a single cavity filled with up conversion crystal grains in accordance with the invention;

FIG. 6 is a schematic representation of a conversion device in accordance with exemplary embodiments of the invention showing in particular the light absorption and emission processes;

FIG. 7 is a schematic representation of a conversion device in accordance with exemplary embodiments of the invention.

### DETAILED DESCRIPTION OF THE INVENTION

The disclosure of U.S. Provisional Patent Application No. 61/374,050, filed on Aug. 16, 2010, is incorporated by reference herein.

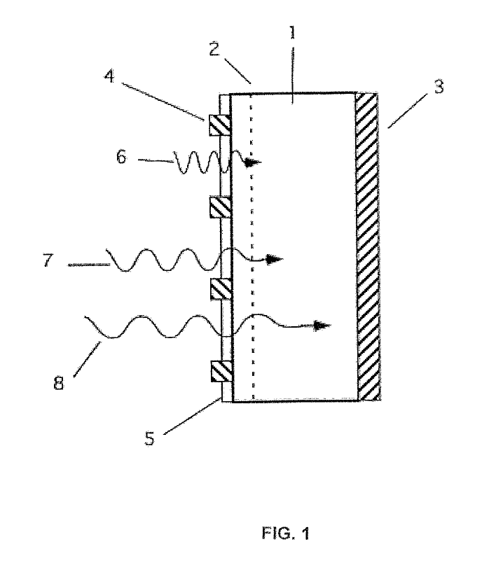

An energy conversion device according to the present invention, for example, a photovoltaic solar cell, can be understood by reference to FIG. 1, which illustrates a simplified solar cell formed from a semiconductor 1. Examples of absorbing semiconductors are Si, GaAs, and cadmium telluride (CdTe). As has been previously discussed, a semiconductor is characterized by E_{G}. Referring to FIG. 1, a p/n junction 2 is used to separate photogenerated pairs (electrons and holes, or “e-h pairs”). Electrical contact is made by contact elements, such as a back contact 3 and a front contact grid, which usually has a plurality of interconnected contact lines 4. Reflectance of the absorbing semiconductor 1 may be reduced by an antireflection coating 5 applied to the front surface upon which light rays are incident. In FIG. 1, light rays 6, 7, 8 represent three spectral bands in the incident solar flux.

The three solar light rays 6, 7, 8 represent all of the solar photons incident on the solar cell. Ray 6 comprises photons each with energy greater than E_{G}. Ray 7 comprises photons with energy approximately equal to E_{G}. Ray 8 comprises photons with energy less than E_{G}. It should be understood that solar photons generally are incident uniformly on the surface of the solar cell independent of energy, and this representation of individual rays is for illustrative purposes.

The absorption of photons in semiconductor 1 depends highly on the energy; thus, it is appropriate to consider photons in three groups as represented by rays 6, 7, and 8. The spectral bands associated with rays 6, 7, and 8 depend on the value of E_{G} of the absorbing semiconductor. For example, for silicon at room temperature, ray 6 corresponds to photons with wavelength shorter than 1110 nm; ray 7 corresponds to photons with wavelength approximately equal to 1110 nm, and ray 8 corresponds to photons with wavelength greater than 1110 nm.

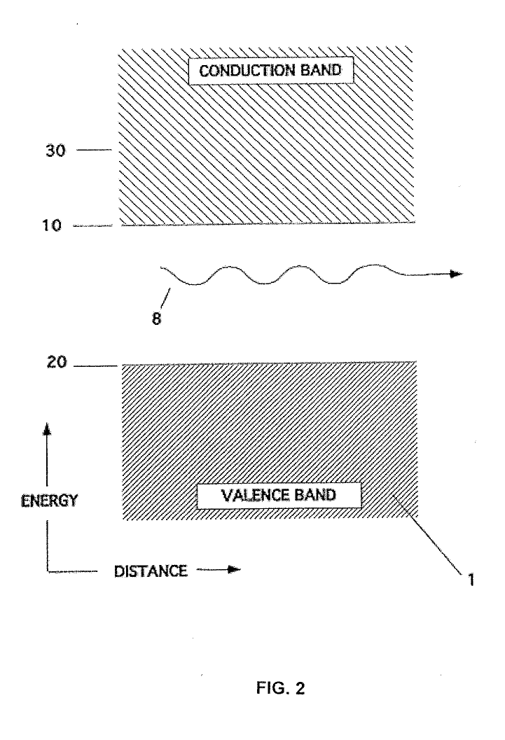

FIG. 2 illustrates a simplified energy band diagram that depicts electron energy on the ordinate (“y”) axis and depth into the semiconductor 1 (measured from the front surface of semiconductor 1) on the abscissa (“x”) axis. Electrons associated with optical absorption and emission occupy energy states within the semiconductor, and the states occur in bands called the conduction band and the valence band. Electrons in the conduction band have higher energy than electrons in the valence band. The conduction band has a minimum energy 10 and the valence band has a maximum energy 20. The difference in these energies is the energy band gap E_{G}. Electron energy greater than the valence band maximum energy 20 and less than the conduction band minimum energy 10 is forbidden in a pure semiconductor.

The fundamental photon absorption process in a semiconductor comprises the excitation by a photon of an electron from a state in the valence band to a state in the conduction band. The smallest photon energy for which this process can occur corresponds to an event that raises the energy of an electron at the valence band state of maximum energy 20 to the conduction band state of minimum energy 10, and energy less than this difference is insufficient for absorption. In other words, photons with energy less than E_{G} cannot excite an electron from the valence band to the conduction band, and such photons are not usefully absorbed. In FIGS. 1 and 2, ray 8 is shown comprising photons with energy less than E_{G} as passing through the material without absorption. In a conventional photovoltaic cell the energy of such photons is lost, and this loss is called a “non-absorption loss.”

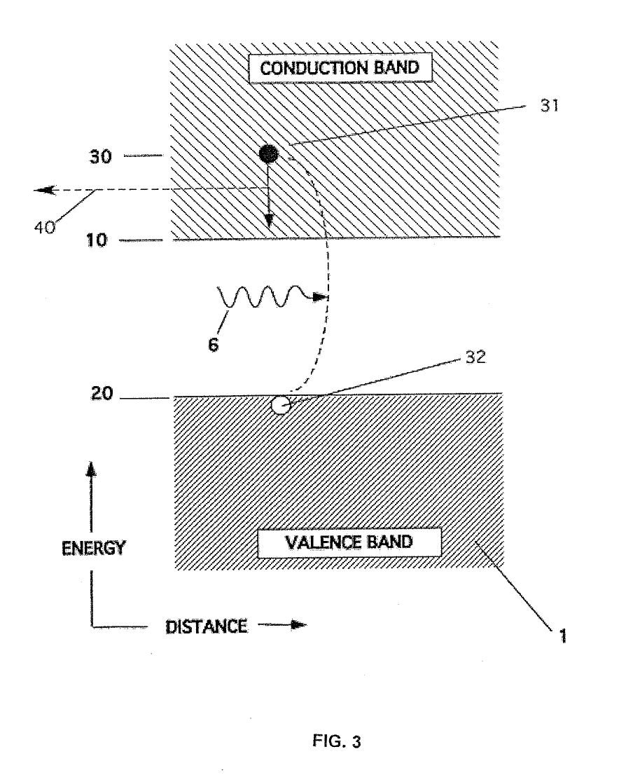

With reference to FIG. 3, a photon in ray 6 having energy greater than E_{G} is absorbed by exciting an electron 31 from the valence band to the conduction band, leaving a hole 32 in the valence band. The photon provides energy to the electron that is greater than E_{G} and thus the resultant energy 30 of the excited electron is greater than the conduction band minimum energy 10. Almost immediately this electron loses this excess energy to heat (lattice excitation) 40 as it relaxes to the conduction band minimum energy 10. The energy provided by the photon that is in excess of E_{G} is lost. This loss is called a “thermalization loss.” The thermalization and non-absorption losses are both zero only if the photon energy is equal to E_{G}, corresponding to photons in ray 7 of FIG. 1.

In a single-absorber solar cell, the amount of energy lost to (i) non-absorption and (ii) thermalization depends on the band gap E_{G} of the semiconductor from which the solar cell is made, and the incident solar spectrum. Table 1 provides the result of a calculation of these losses for the case of a silicon solar cell, assuming an incident spectrum with a total incident power of 100 mW/cm². Together these losses account for 51 mW/cm² that is therefore unavailable for conversion to electricity by a silicon solar cell. A loss of a similar magnitude would result from the use of any single semiconductor in a solar cell having E_{G} in the range of about 1 to 1.5 eV. (Beyond this range, the total energy loss would be greater.)

TABLE 1
Summary of Power Loss in Silicon Solar Cells

| Power source or loss | Power (mW/cm²) |
|---|---|
| Total Incident Power (insolation) | 100 (AM1.5) |
| Power Lost to Thermalization (E > E_{G}) | −32 |
| Power Lost to non-absorption (E < E_{G}) | −19 |
| Net power available after absorption | 49 |
| Voltage and fill factor losses | −19 (approximate) |
| Practical power limit | 30 |

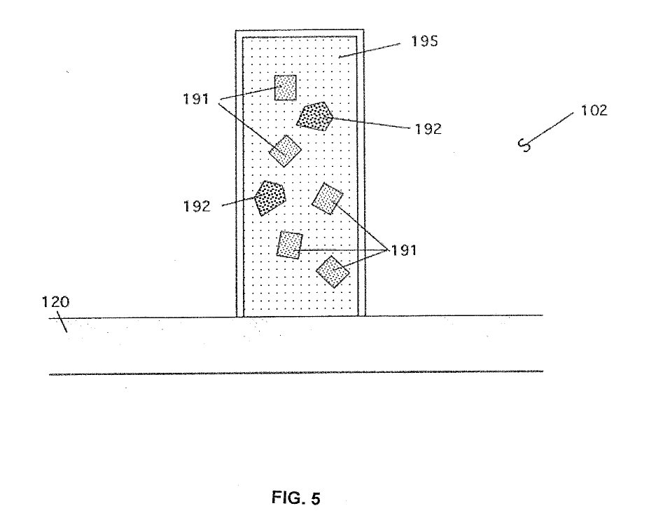

The present device reduces these losses by converting the wavelengths of the incident photons prior to absorption by the semiconductor. FIG. 5 illustrates one exemplary embodiment of an energy conversion device in which Si is used as the photon-absorbing semiconductor. Si can be chosen for low cost, but aspects of the design shown herein are applicable to other semiconductors. In the embodiment shown in FIG. 5, a solar cell 100 is formed from p-type Si 102 that is provided with an n-type front layer to form a p/n junction 103, an antireflection coating 104 on which light rays 106 are incident, and front metal grid 105. The front surface may be texture-etched. Methods of forming such structures are well-known in the art of fabricating Si solar cells. For example, the n-type layer may be formed by phosphorus ion implantation and annealing, the anti-reflection coating may be a plasma-enhanced CVD layer of silicon nitride (Si₃N₄), and the metal grid may be photolithographically patterned evaporated metal such as Ti—Pd—Ag, followed by electroplated Ag. Alternatively the metal grid may be formed by screen-printed Ag.

As shown in FIG. 5, the back surface of the silicon 102 is etched to provide cavities 125 that are filled with an up conversion composite material 130. The cavities are shown with rectangular cross section, but they may have any shape including v-grooves. In one example, the cavities may have a depth of 2×10⁻⁴ m and a width of 1×10⁻⁴ m, and the center-to-center spacing of the cavities may be 2×10⁻⁴ m. All surfaces of the silicon that are not to be provided with metallization are coated with a thermally grown dry oxide (such as silicon dioxide) to minimize surface recombination, and p⁺ doping may be used on the back to create a back surface field (BSF). If the p⁺ doping is patterned (for example by ion implantation through a mask), it may be used as a selective etch mask for the formation of the cavities, since potassium hydroxide and other etches are known for high etch rate selectivity between p and p⁺ silicon. The back surface is also provided with metallization 140 on a large fraction (>25%) of the surface to facilitate electrical and thermal contact with a back heat spreader and heat sink 150, which may be formed from a material such as copper that has high electrical and thermal conductivity. Preferably material 140 reflects light diffusely from its surface 120.

Materials suitable for wavelength conversion are known. For example, fluorinated crystals such as NaYF₄, BaY₂F₈ and KY₃F₁₀ doped with rare earth elements such as Er are known to provide both up and down conversion. For instance, Er-doped NaYF₄ is known to absorb infra-red photons and emit visible photons. The physics of up and down conversion involves cooperative processes comprising nonradiative energy exchange between electrons in rare earth elements that occupy crystal lattice sites in close proximity. Up conversion using Er doping converts two photons with wavelength in the range of 1500 to 1600 nm to one photon with wavelength of approximately 980 nm. Since photons in the range 1500 to 1600 nm are not absorbed by Si, by converting these photons to a single photon at 980 nm, the energy is converted to a form that can be absorbed by Si. In this way, up conversion can increase the photo-generated current of a Si solar cell.

The up conversion composite material 130 filling the cavities 125 is formed from grains of up-conversion crystals dispersed in a continuous medium formed from an optical material that permits transmission of photons, at least in the spectrum of interest for operation of the solar cell and the up conversion materials. The grains may be in the form of a single powder or mixture of different powders. The grain sized should be smaller than the width and depth of the cavity; for example, a grain size less than 100 microns would be suitable in a cavity having a width of 200 microns.

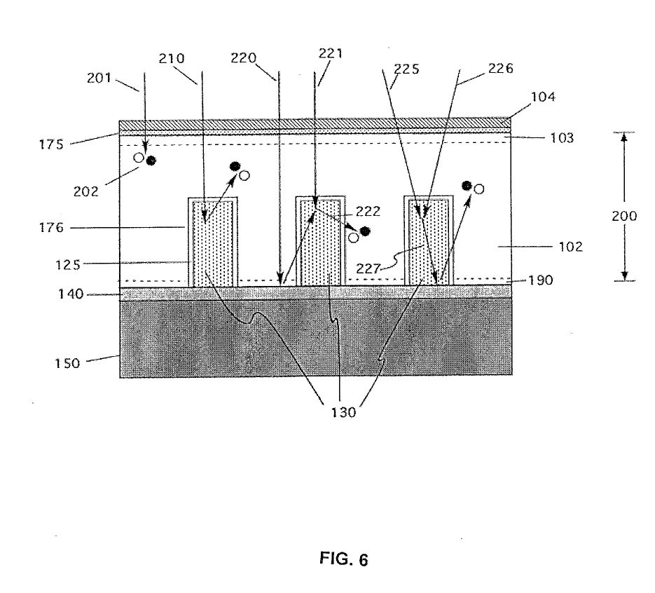

FIG. 6 shows two types of crystal grains 191, 192, dispersed in an optical material 195. The use of grains with different rare earth doping broadens the absorption spectrum of the composite, while preventing interactions between the two different dopants. Since the two dopants are each confined to different crystal grains, they cannot exchange energy by nonradiative energy transfer. If a single grain were doped with two rare earth dopants to increase the absorption, there can be deleterious effects between the two dopant types, which is avoided when the dopants are confined to separate grains. For example, the dopants Er and Ho can be separated. Alternatively, some dopant combinations can be favorable when present in the same grain, such as Er and Yb. The present invention allows the mixing of favorable combinations and the separation of unfavorable combinations.

The optical material 195 may be an optical adhesive, such as a thermally cured epoxy. The optical dispersion medium has an index of refraction that is different than the index of refraction of the up conversion powders. Preferably the index of refraction of the dispersion medium is intermediate between the index of refraction of semiconductor material 102 and the index of refraction of the powder grains. In one embodiment, the up converter grains 191 are NaYF₄ doped with Er, the up converter grains 192 are NaYF₄ doped with Ho, and the optical medium 195 is the optical adhesive commercially available as Norland 83H. The crystals have an index of refraction of approximately 1.47, the optical adhesive has an index of refraction of 1.56, and the mixture is embedded in cavities formed in Si which has an index of refraction of approximately 3.62.

While these embodiments have described two crystal powders mixed with optical epoxy to form the upconverter material, any number of different types of crystal powders may be mixed. Other up conversion materials can include, for example, quantum dots made of, for example, PbS, PbSe, CdS, CdSe, as well as various other semiconductors and carbon nanotubes, can provide for wavelength conversion. Any of these materials can be doped with rare earth elements or other elements. Also, some dopants benefit by incorporation of Yb as a second dopant in the same grain; thus, two dopants can be in one grain if one of the dopants is Yb. While we have described embodiments in which the absorbing material 102 is p-type Si, the absorber may also be n-type silicon, in which case the emitter region 103 is formed by p-type Si, and the back surface field region 190 is formed from highly doped n-type silicon. Alternatively, the solar cell absorber material 102 may be any semiconductor and is not limited to Si. The optical dispersion medium can be any material that holds the crystal grains in dispersion and transmits photons in the spectrum of interest, such as the visible and infrared portion. The wider the transmission band of the dispersion medium, the more general the applicability of the device.

The cavities can be filled in any suitable manner. For example, the cavities can be filled with the powders, then back filled with an optical epoxy and cured. In another method, the powders and an optical epoxy can be mixed, then filled in to the cavities and cured. In any method, air entrapment should be avoided. Air can be removed by, for example, the use of a vacuum. Techniques used for filling small cavities in the manufacturing of LCDs can be adapted.

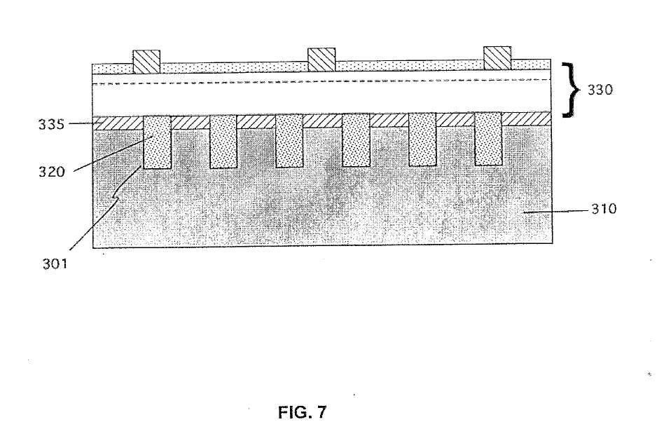

Operation of the energy conversion device is described more fully in conjunction with FIG. 7. A solar cell is formed from p-type Si 102, having a thickness 200, with a front n-type emitter 103 to create a p/n junction solar cell. The thickness 200 may be between 3×10⁻⁴ m and 5×10⁻⁴ m. A highly doped p-type back surface field region 190 is formed on the back of the Si. Cavities are etched and a thermal oxide 176 is grown on the inside of the cavities and a front thermal oxide 175 is grown on the front surface of the emitter 103. The thermal oxides reduce surface recombination velocity. The front is provided with an antireflective coating 104. The cavities are filled with up conversion material 130.

In this device, light may be converted to electricity in a number of ways. FIG. 7 shows a light ray 201 that has a wavelength shorter than the absorption edge of the semiconductor material 102 and that is therefore absorbed by the material 102 to create an electron hole pair 202. The electron hole pair 202 diffuses to the p/n junction where it is collected and separated in a manner well known in the art of solar cells. Light ray 210 illustrates a different process, in which a photon with wavelength shorter than the absorption edge of the material 102 is scattered by the up conversion material 130. The scattering is a result of Fresnel reflection owing to the difference in index of refraction between the grains of powder and the adhesive. The scattering increases the path length of the photon in material 102 and allows the thickness 200 of material 102 to be reduced without loss of photo-generated current. The examples provided by rays 201 and 210 are directly absorbed without upconversion.

Rays 220 and 221 have wavelengths longer than the absorption edge of material 102 and therefore cannot be directly absorbed by material 102. Ray 220 reflects diffusely from the back metallization 140 and enters an upconverter material 130 where it is absorbed by a dopant atom in a crystal grain (for example 191 or 192 in FIG. 6). Ray 221 enters the upconversion material 130 and is absorbed in the same crystal grain. Owing to nonradiative energy exchange, a photon 222 is produced that can be absorbed by material 102. This photon 222 generates an electron hole pair which diffuses to the p/n junction and is separated. In one embodiment, the solar cell material 102 is Si having an absorption edge of approximately 1100 nm, and photons 220 and 221 have a wavelength of 1550 nm. The resultant photon has a wavelength of 972 nm.

A similar process is illustrated by photons 225 and 226 in FIG. 7. Since radiation in the up conversion process is emitted isotropically, half of the radiation will be propagating toward the back of the solar cell. In this example, the resultant photon 227 is propagating toward the back of the solar cell; however, it is reflected by the back metallization 140 and eventually reaches the material 102 where it may create an electron hole pair.

In this manner, optical coupling between the semiconductor material and the up conversion material is increased over prior art devices. The use of multiple up conversion materials minimizes non-absorption and thermalization losses by increasing the size of the spectral bands than can be absorbed by the solar cell. This is an improvement over the use of a single up conversion material that only absorbs over a few narrow bands of the spectrum. The energy conversion device can be used in a single junction solar cell, providing higher efficiency with more economical manufacturing than a tandem solar cell structure.

Turning now to a further embodiment illustrated in FIG. 8, the cavities 301 may be formed in a heat spreader 310 bonded to the back of the solar cell. Processes such as reactive ion etching, machining, and laser drilling can form cavities 301 in metals such as copper to form a patterned heat spreader 310. The cavities 301 can be coated with Ag, such as by Ag electroplating, so that the internal surfaces are highly reflective. The cavities are then filled with up converter material 320. The up converter substrate is then ready for bonding of the solar cell 330 to it. In this manner, greater electrical and thermal coupling can be provided between the solar cell and the heat sink. The embodiment of FIG. 8 may be particularly well suited to use with thin semiconductors that do not have the volume needed to form the cavity. This embodiment can also be used with Si if the Si wafer is too thin to support deep cavities.

If the solar cell 330 is GaAs or another very thin solar epitaxial cell material, the substrate must be removed because the minority carrier diffusion length is too short for electron hole pairs, generated at the back of the substrate by absorption of an up conversion photon, to diffuse to the front where they would be collected by the p/n junction. Accordingly, the substrate must be removed so that electron hole generation occurs in an active layer of the solar cell near the p/n junction. Techniques known in the art as epitaxial liftoff can be used to remove active epitaxial layers from the substrate and to apply them to the up converter heat spreader. In one embodiment, epitaxial GaAs is grown on a substrate prepared with an etch stop or release layer (such as AlAs), followed by formation of front side metallization and deposition of the antireflection coating (similar to the front side processing of Si). After front side processing and application of a solar cell cover glass, the substrate is removed. The back side can be metallized using patterning methods known in the art. The spacing of the metallization pattern 335 (FIG. 8) may be the same as the spacing of the up converters on the heat spreader. (It will be appreciated that FIG. 8 is not to scale, and the metallization pattern 335 and the grooves therein are illustrated with an exaggerated thickness. For example, the cavities in the heat spreader may be 200 microns deep, whereas the grooves in the metallization pattern may be only 25 microns deep or less if electrical contact with the heat spreader is good.) This type of heat spreader and heat sink can also be applied to Si.

The energy conversion device described herein can be used in combination with other devices. For example, a down conversion device can be applied to the front side of the solar cell described herein. The formation of down converters on the front of solar cells are described in copending U.S. patent application Ser. No. 12/778,365, filed on May 12, 2010, incorporated by reference herein.

Many single semiconductor and multiple semiconductor combinations have been used to create solar cells. While exemplary embodiments of the invention are primarily shown and described as Si solar cells, it is understood that embodiments of the invention are applicable to a wide variety of solar cells, as well as energy conversion devices that are not photovoltaic solar cells. Additionally, it will be appreciated that various features explicitly described in conjunction with a particular embodiment can also be used with other embodiments even if not explicitly described in conjunction therewith.

Having described exemplary embodiments of the invention, it will now become apparent to one of ordinary skill in the art that other embodiments incorporating their concepts may also be used. The embodiments contained herein should not be limited to disclosed embodiments but rather should be limited only by the spirit and scope of the appended claims.

What is claimed is:

1. An energy conversion device, comprising:
a layer of a photon-absorbing semiconductor material having a front photon-receiving surface and a back surface, the semiconductor material having an absorption edge;
cavities formed in the photon-absorbing semiconductor material extending inwardly from the back surface;
an up conversion composite material disposed within the cavities, the up conversion material comprising:
a mixture of at least two different up conversion materials formed as crystal grains dispersed within a dispersion medium comprising an optically transmitting material, each up conversion material capable of absorbing photons having wavelengths longer than the absorption edge of the semiconductor material and emitting photons having wavelengths shorter than the absorption edge, each up conversion material being different to absorb photons having different wavelengths.

2. The device of claim 1, wherein the up conversion materials include crystal grains comprised of a crystal material doped with dopant atoms capable of absorbing photons having wavelengths longer than the absorption edge of the semiconductor material and emitting photons having wavelengths shorter than the absorption edge.

3. The device of claim 2, wherein the dopant atoms include Er, Ho, or Yb.

4. The device of claim 2, wherein the dopant atoms comprise atoms selected from the group consisting of rare earth elements.

5. The device of claim 1, wherein the mixture of up conversion materials comprises a mixture of grains of NaYF₄ doped with Er and grains of NaYF₄ doped with Ho.

6. The device of claim 1, wherein the up conversion materials include quantum dots capable of absorbing photons having wavelengths longer than the absorption edge of the semiconductor material and emitting photons having wavelengths shorter than the absorption edge.

7. The device of claim 6, wherein the quantum dots are formed of PbS, PbSe, CdS, or CdSe.

8. The device of claim 1, wherein the mixture of up conversion materials has an index of refraction that is less than an index of refraction of the photon-absorbing semiconductor material, and the dispersion medium has an index of refraction that is between the index of refraction of the mixture of up conversion materials and the index of refraction of the photon-absorbing material.

9. The device of claim 1, wherein the dispersion medium comprises an optical epoxy.

10. The device of claim 1, wherein the cavities are lined with a thermal oxide material.

11. The device of claim 1, wherein the photon-absorbing semiconductor material comprises Si.

12. The device of claim 1, wherein the semiconductor material comprises a p-type material, and the layer of the semiconductor material includes a p/n junction formed at the front surface.

13. The device of claim 1, wherein the layer of the semiconductor material includes a p-type back surface field region formed at the back surface.

14. The device of claim 1, further comprising electrical contact elements located on the front surface and the back surface.

15. The device of claim 1, further comprising a thermal oxide material on the front surface of the layer of semiconductor material.

16. The device of claim 1, further comprising an antireflective coating on the front surface of the layer of semiconductor material.

17. The device of claim 1, further comprising a reflective material located on the back surface of the layer of semiconductor material.

18. The device of claim 1, further comprising a heat spreader in thermal contact with the layer of semiconductor material at the back surface.

19. The device of claim 1, wherein the layer of semiconductor material and the up conversion material disposed within the cavities comprise a photovoltaic solar cell.

20. An energy conversion device comprising:
a first layer comprising a photon-absorbing semiconductor material having a front photon-receiving surface and a back surface, the semiconductor material having an absorption edge;
a second layer comprising a heat spreader layer in thermal communication with the first layer at the back surface; and
an up conversion composite material disposed in a plurality of discrete bodies, each of the bodies in optical contact with the first layer, the up conversion composite material comprising:
a mixture of at least two different up conversion materials formed as crystal grains dispersed within a dispersion medium comprising an optically transmitting material, each up conversion materials capable of absorbing photons having wavelengths longer than the absorption edge of the semiconductor material and emitting photons having wavelengths shorter than the absorption edge, each up conversion material being different to absorb photons having different wavelengths.

21. The energy conversion device of claim 20, further comprising a plurality of cavities disposed in the first layer extending inwardly from the back surface, and each of the bodies of the up conversion material is disposed in one of the cavities

22. The energy conversion device of claim 20, further comprising a plurality of cavities disposed in the second layer extending inwardly from a surface of the second layer, and each of the bodies of the up conversion material is disposed in one of the cavities.

23. The device of claim 20, wherein the cavities are lined with a reflective material.
